(19) United States
(12) Patent Application Publication
(10) Pub. No.: US 2005/0260356 A1
(43) Pub. Date: Nov. 24, 2005

(54) Microcontamination abatement in semiconductor processing

(75) Inventors: Hemant P. Mungekar, San Jose, CA (US); Bikram Kapoor, Santa Clara, CA (US); Zhuang Li, San Jose, CA (US)

Correspondence Address: Patent Counsel;Applied Materials, Inc., M/S 2061, P.O. Box 450A, Santa Clara, CA, 95052, US

(73) Assignee: APPLIED MATERIALS, INC., Santa Clara, CA (US)

(21) Appl. No.: 10/847,922

(22) Filed: May 18, 2004

(51) Int. Cl. C23C 16/00

(52) U.S. Cl. 427/569; 427/248.1; 427/585

(57) ABSTRACT

A film is deposited over a substrate by flowing a process gas to a process chamber and flowing a fluent gas to the process chamber. The process gas includes a silicon-containing gas and an oxygen-containing gas. The fluent gas includes a flow of helium and a flow of molecular hydrogen, the flow of molecular hydrogen being provided at a flow rate less than 20% of a flow rate of the helium. A plasma is formed in the process chamber with a density greater than 10^{11 ions/cm}³. The film is deposited over the substrate with the plasma.

### BACKGROUND OF THE INVENTION

One class of techniques that is commonly used in the semiconductor-processing industry for depositing films on substrates is chemical-vapor-deposition (“CVD”) techniques. Conventional thermal CVD processes supply reactive gases to the substrate surface where heat-induced chemical reactions take place to produce the desired film. Plasma-enhanced CVD (“PECVD”) techniques promote excitation and/or dissociation of reactant gases by the application of radio-frequency (“RF”) energy to a reaction zone near the substrate surface, thereby creating a plasma. The high reactivity of the species in the plasma reduces the energy required for a chemical reaction to take place, and thus lowers the temperature required for such CVD processes when compared with conventional thermal CVD processes. These advantages may be further exploited by high-density-plasma (“HDP”) CVD techniques, in which a dense plasma is formed at low vacuum pressures so that the plasma species are even more reactive. While each of these techniques falls broadly under the umbrella of “CVD techniques,” each of them has characteristic properties that make them more or less suitable for certain specific applications.

For instance, HDP-CVD has often been favored for gapfill processes, in which the deposited film is to fill a gap defined between adjacent raised structures, such as may occur in shallow-trench-isolation (“STI”), premetal-dielectric (“PMD”), or intermetal-dielectric (“IMD”) applications, among others. One challenge with such gapfill processes is to ensure that the material is deposited in the gap without forming a void. This challenge is illustrated schematically with the cross-sectional views shown in FIGS. 1A and 1B. FIG. 1A shows a vertical cross section of a substrate 110, such as may be provided with a semiconductor wafer, having a layer of features 120. Adjacent features 120 define gaps 114 that are to be filled with dielectric material, with the sidewalls 116 of the gaps being defined by the surfaces of the features 120. As the deposition proceeds, dielectric material 118 accumulates on the surfaces of the features 120, as well as on the substrate 110, and forms overhangs 122 at the corners 124 of the features 120. As deposition of the dielectric material 118 continues, the overhangs 122 typically grow faster than the gap 114 in a characteristic breadloafing fashion. Eventually, the overhangs 122 grow together to form the dielectric film 126 shown in FIG. 1B, preventing deposition into an interior void 128.

Gapfill using HDP-CVD has tended to be useful because the high density of ionic species in the plasma during HDP-CVD processes causes there to be sputtering of the film even while it is being deposited. This simultaneous sputtering and deposition of material during the deposition process tends to keep the gap open during deposition. Even this effect has been found to have limits, though, in light of recent trends to reduce the width of gaps and to increase their aspect ratios to increase the density of circuit elements. With such more aggressive gapfill applications, one effect that has been found helpful is to use a flow of helium as a fluent gas to carry the reaction gases to the substrate. The use of helium is especially suitable for improving gapfill in applications having gaps of a certain size, particularly in the range of about 90-150 nm.

The inventors have discovered, however, that the use of helium as a fluent gas significantly increases particle-contamination levels, most of the particle contaminants having sizes below about 2 μm. Such contamination may interfere adversely with the operation of devices formed using the helium-based deposition and gapfill processes. There is accordingly a need in the art for methods to abate of the contamination when using a helium-based HDP-CVD gapfill process.

### BRIEF SUMMARY OF THE INVENTION

The inventors have discovered that including a small flow of hydrogen in an HDP-CVD deposition process based on the use of a helium fluent flow acts to reduce levels of microcontamination. The inventors hypothesize that the inclusion of such a hydrogen flow increases a driving force for a backwards dissociation reaction that thereby limits the presence of growth cores in the high-density plasma.

In some embodiments, a film is thus deposited over a substrate by flowing a process gas to a process chamber and flowing a fluent gas to the process chamber. The process gas comprises a silicon-containing gas such as SiH₄ and an oxygen-containing gas such as O₂. The fluent gas comprises a flow of helium and a flow of molecular hydrogen, the flow of molecular hydrogen being provided at a flow rate less than 20% of a flow rate of the helium. A plasma is formed in the process chamber with a density greater than 10¹¹ ions/cm³. The film is deposited over the substrate with the plasma.

In some embodiments, the flow of molecular hydrogen may be provided at even lower flow rates relative to the helium flow, being provided at less than 10% of the flow rate of the helium in one embodiment and at less than 5% of the flow rate of the helium in another embodiment. The flow rate of the helium may be between 100 and 1000 sccm in an embodiment. In some instances, an additional flow of an inert gas may be provided at a flow rate less than 10% of the flow rate of the helium, allowing sputter characteristics during the HDP-CVD deposition to be modified. Such characteristics may also be modified in other ways, such as by applying a negative bias to the substrate. An interior pressure of the process chamber may be maintained less than 10 mtorr.

A further understanding of the nature and advantages of the present invention may be realized by reference to the remaining portions of the specification and the drawings.

### BRIEF DESCRIPTION OF THE DRAWINGS

FIGS. 1A and 1B are schematic cross-sectional drawings illustrating the formation of a void during a gapfill process;

FIG. 2A is a schematic illustration of the formation of a expansion of gas at a nozzle tip within a process chamber, where pyrolysis of precursor gases may be initiated by a shock front;

FIG. 2B is a schematic illustration of flows in an HDP-CVD process chamber, showing recirculation zones where high residence time may promote particulation;

FIG. 2C is a schematic illustration of forces on plasma particles that may contribute to contaminant growth;

FIG. 3A provides experimental results of tests using a 200-mm wafer to evaluate the effect of including a flow of H₂ with a He fluent gas in an HDP-CVD deposition process;

FIG. 3B provides experimental results of tests using a 300-mm wafer to evaluate the effect of including a flow of H₂ with a He fluent gas in an HDP-CVD deposition process;

FIG. 4 provides a flow diagram summarizing embodiments of the invention that include a flow of H₂ with a He fluent gas in an HDP-CVD deposition process;

FIG. 5A is a simplified diagram of one embodiment of an HDP-CVD system according to the present invention; and

FIG. 5B is a simplified cross section of a gas ring that may be used in conjunction with the exemplary HDP-CVD processing chamber of FIG. 5A.

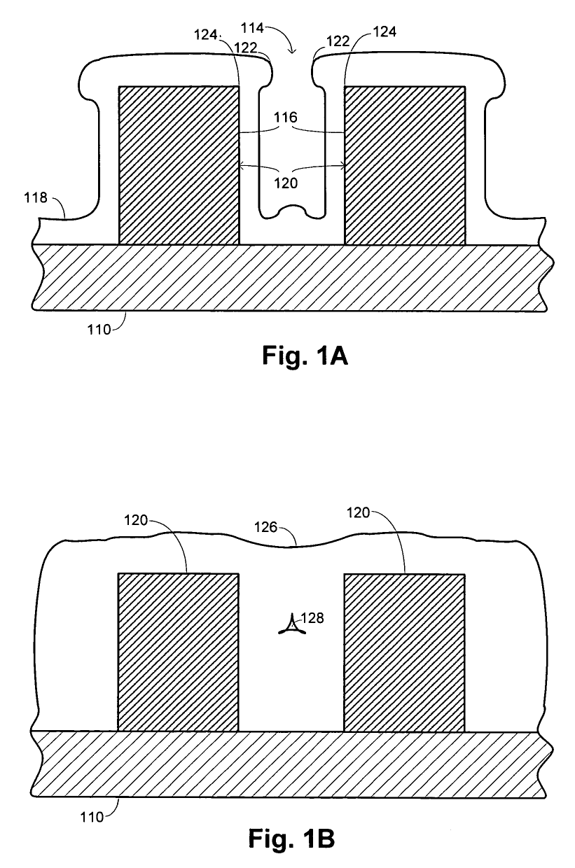

### DETAILED DESCRIPTION OF THE INVENTION

When confronted with the discovery of increased microcontaminants in HDP-CVD deposition processes that use He as a fluent gas, the inventors set out to identify potential mechanisms that might be the source of the contaminants, particularly when compared with similar processes that are based on the principal use of another fluent gas like Ar. Their initial consideration focused on the deposition of undoped silicate glass (“USG”) deposited using flows of SiH₄ and O₂ as precursor gases for film formation. In such processes, the flows of SiH₄ and O₂ may be accompanied by a flow of the fluent gas, with the inventors having observed significantly greater levels of microcontamination associated with a He flow than with an Ar flow.

The inventors considered a number of potential mechanisms that might be providing the contamination. For example, one mechanism that was considered relates to the fact that heating of the process chamber in which the deposition takes place causes thermal expansion of components. Flaking of aluminum particles from the process chamber may result from such heating and the fact that there is a mismatch between the coefficients of thermal expansion for silicon oxides and aluminum oxides. The effect of this mechanism may be greater with a He flow than with an Ar flow because the temperature in the chamber is generally slightly higher with the He flow than with the Ar flow. The contribution of this effect is believed to be small, however, because the temperature difference between the processes is not great and the inventors have been unable to identify that the difference has an effect on the chemistry of the processes.

Other mechanisms that the inventors deduced were more likely to result in the contamination were related to decomposition of the silane SiH₄, in particular to silane pyrolysis, gas-phase nucleation and growth of microcontaminants, and surface growth of microcontaminants in electrostatic traps. Silane decomposition SiH₄→Si+SiHₓ+H_{y} is believed to be enhanced with a He fluent because a driving force for a backwards reaction is inhibited in the presence of He.

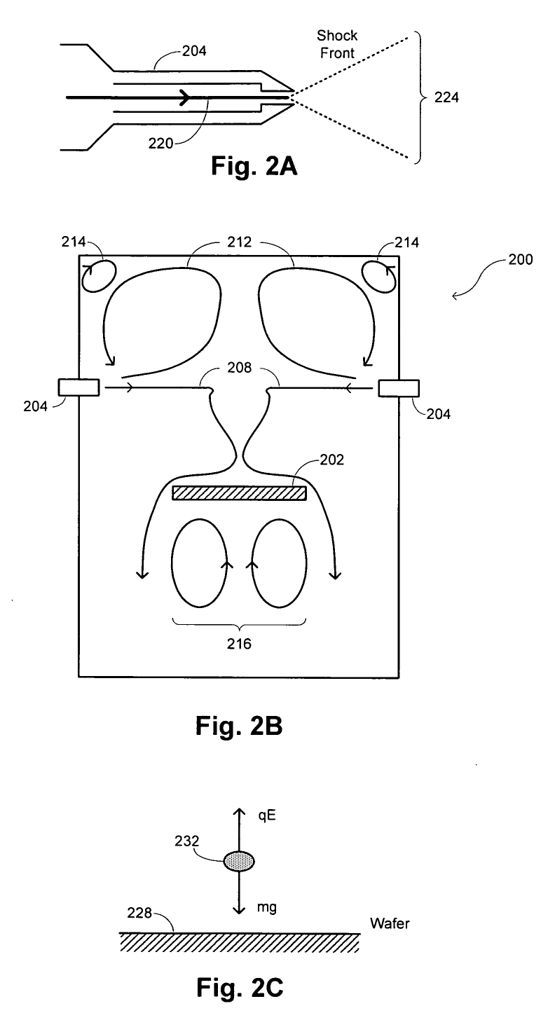

FIGS. 2A-2C are schematic illustrations of how the silane decomposition mechanisms may result in the formation of significant levels of microcontaminants. FIG. 2A provides a schematic illustration of gas expansion at the tip of a nozzle 204 that provides a flow of gas to a process chamber. Modeling results have established that during processing, the nozzle tip 204 may reach temperatures of about 800° C. for a 2.55″ nozzle used in a chamber for 200-mm wafers. Such a high temperature promotes a cracking phenomenon that causes rapid thermal decomposition of the incoming silane and propagation of the resultant species along a shock front 224. The dissociated Si and SiHₓ species may then act as cores for growth of other silicon or silane-based particles in the chamber.

FIG. 2B illustrates flow patterns that may result for the species within the process chamber 200, particularly for nozzles 204 positioned to provide side flows to the chamber 200. The approximately rectangular cross-section of the chamber 200 is merely illustrative; chambers may have complicated interior shapes that affect the resultant flow patterns in complex ways, but the general observations made here are true for most such chambers. The flow of dissociated species from the side nozzles 204 may break into multiple component flows. One flow 212 may flow upstream in a recirculation pattern, and may additionally divide to produce recirculation eddies 214. Another flow 208 may flow towards a wafer pedestal 202 in the chamber 200 and with eddy action produce recirculation zones 216 below the pedestal. The residence time of particles is significant in such recirculation zones 212, 214, and 216, allowing the cores produced by silane decomposition time to grow through interaction with other particles in the chamber 200. The growth resulting from the presence of such recirculation zones may be enhanced with He-based processes because they are generally run for a longer time than Ar-based processes when depositing comparable films.

In addition to gas-phase nucleation in recirculation zones promoting contaminant-particle growth, the fact that the decomposition species are charged may result in trapping such species in electrostatic traps, thereby also providing growth centers. This is illustrated schematically with FIG. 2C, which shows forces acting on charged particle 232 above the wafer 228. The downwards gravitational force mg acting on the particle 232 as a result of its mass m when subject to a gravitational acceleration g may be approximately balanced in some regions by an opposite electrical force qE as a result of its charge q in electric field E. While the presence and location of such electrostatic traps depends on the direction and strength of the electric field E throughout the chamber, FIG. 2C illustrates that in many instances such traps exist over the wafer, resulting in surface growth of microcontaminants.

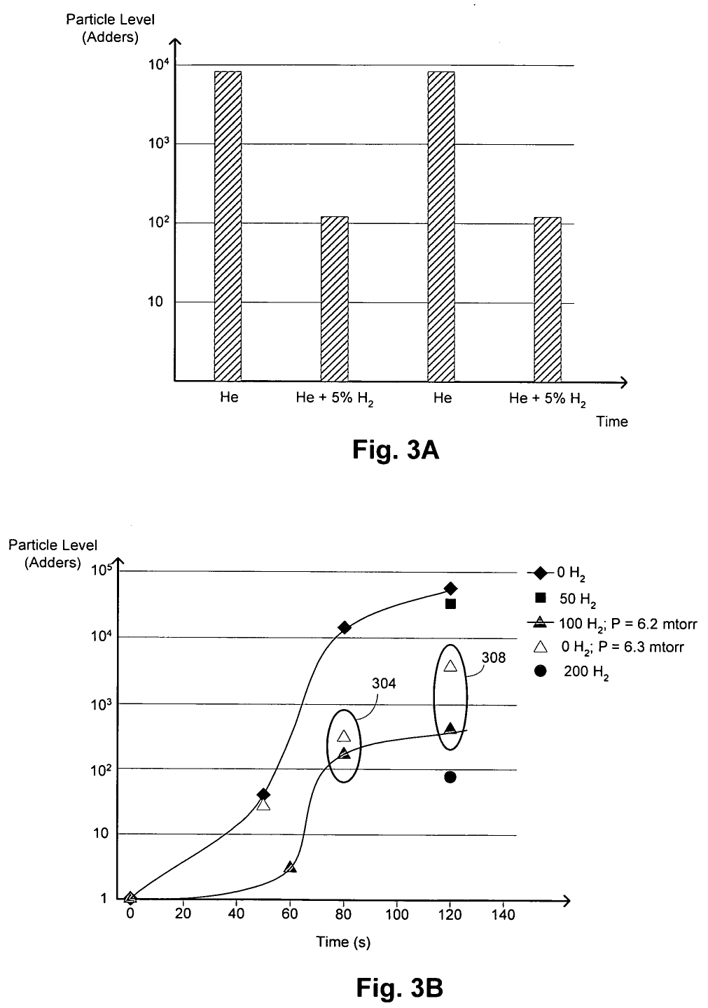

When considering these potential contamination mechanisms that result from silane decomposition, the inventors hypothesized that a driving force for the backwards reaction could be restored by including a relatively small flow of H₂ with the He fluent-gas flow. By restoring such a driving force, the backwards reaction would act to inhibit the growth of microcontaminants. A number of experiments were carried out to test the hypothesis, the results of which are shown in FIGS. 3A and 3B, both of which are semilogarithmic plots so that variations in the ordinate direction are compressed. The results of FIG. 3A were generated by performing experiments using a 200-mm wafer, and the results of FIG. 3B were generated with experiments using a 300-mm wafer.

In the initial tests, in addition to providing flows of SiH₄ and O₂, a flow of He was provided to the process chamber at a flow rate of 400 sccm and periodically a flow of H₂ was also provided at a flow rate of 20 sccm. The particle levels were measured during phases when the fluent flow was entirely He and during phases when the fluent flow comprised the additional 5% H₂ flow. As the histogram of FIG. 3A demonstrates, the particle levels in the process chamber with the additional H₂ flow are were approximately two orders of magnitude less than the particle levels with purely He fluent-gas flows.

One side effect of including an additional hydrogen flow with the fluent gas is that it causes an increase in pressure in the chamber, which may contribute to a reduction in microcontaminant formation. Accordingly, the subsequent tests on the 300-mm wafer were made both to verify that the microcontaminant reduction from including hydrogen in the fluent flow was reproducible and to determine to what extent that reduction was attributable chemically to the presence of the hydrogen. The baseline for the tests are shown with the solid diamonds and used a helium flow of about 1000 sccm, with no hydrogen flow. A result from additionally providing a flow of 50 sccm of H₂ is shown with the solid square, and shows a significant reduction in particle level. The shaded triangles show a further reduction in particle level resulting from a further increase in H₂ flow rate to 100 sccm, and the shaded circle shows a still further reduction in particle level resulting from a H₂ flow rate of 200 sccm. The trend of these results confirms the conclusion of the 200-mm-wafer results of FIG. 3A that the inclusion of a hydrogen flow causes a reduction in particle level.

The chamber pressure with the 100 sccm flow of H₂ was measured to be 6.2 mtorr. To evaluate the contribution from a pressure increase resulting from the H₂ flow, particle levels were also measured for a pure He fluent flow with the chamber pressure toggled to 6.3 mtorr, i.e. slightly higher than the pressure with a 100-sccm H₂ flow. These results are shown with the open triangles, which fall intermediate between the baseline pure-He results and the 100-sccm-H₂ results. This confirms that the particle reduction resulting from inclusion of H₂ in the fluent flow has contributions both from the consequent pressure increase and from chemical effects. The reduction that is due to such chemical effects is highlighted in FIG. 3B with ellipses 304 and 308 drawn around the data points that illustrate that effect. In addition to the overall decrease in particle levels, the results of FIG. 3B additionally illustrate that the presence of H₂ also delays the onset of particulation in time.

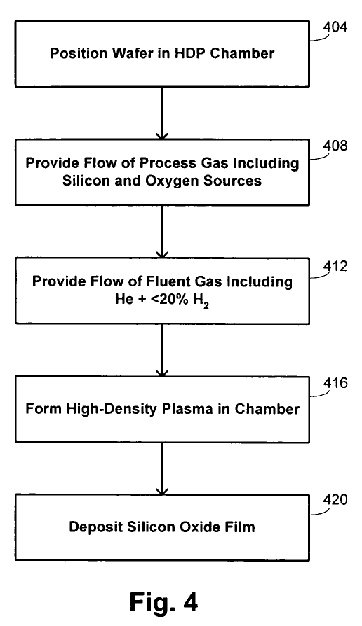

A summary of methods that may thus be used to deposit a film over a substrate with a He-fluent-based HDP-CVD process is provided with the flow diagram of FIG. 4. At block 404, the wafer is positioned in the HDP chamber in preparation for deposition of the film. At block 408, a flow of process gas is provided to the process chamber, including flows of silicon and oxygen sources. In some embodiments, the silicon source comprises a silane such as SiH₄ and the oxygen source comprises molecular oxygen O₂, although silicon-containing gases and oxygen-containing gases may be used in other embodiments. A flow of fluent gas is provided to the process chamber at block 412, the fluent gas including a flow of He and a flow of H₂ in which the flow rate of the H₂ is less than 20% of the flow rate of the He. In some embodiments, the relative flow rate of H₂ to He may be less than 10% or may be less than 5%. The fluent flow may consist of the He and H₂ flows in some instances, but in other instances may include a small additional flow of another inert gas like Ne or Ar to tailor the sputter characteristics of the deposition process to specific applications. Other techniques for tailoring sputter characteristics may include application of a negative bias to the wafer to attract the charged ionic species in the plasma. A high-density plasma is formed in the process chamber at block 416 so that the silicon oxide film may be deposited over the substrate at block 420. As used herein, a “high-density” plasma has a density that exceeds 10¹¹ ions/cm³.

The order of blocks shown in FIG. 4 is not intended to be restrictive and may be modified in some embodiments. For instance, the fluent flow might be provided simultaneously with or earlier than the precursor-gas flow. Formation of the high-density plasma at block 416 may occur earlier in the process than indicated by the ordering of the blocks, such as being formed from just the fluent gas with the precursor gases supplied after plasma formation. In addition, the blocks shown in FIG. 4 are not intended to be exhaustive since the principles of the invention may be used in a variety of applications in which additional or alternative operations are performed as part of the process.

Exemplary Substrate Processing System

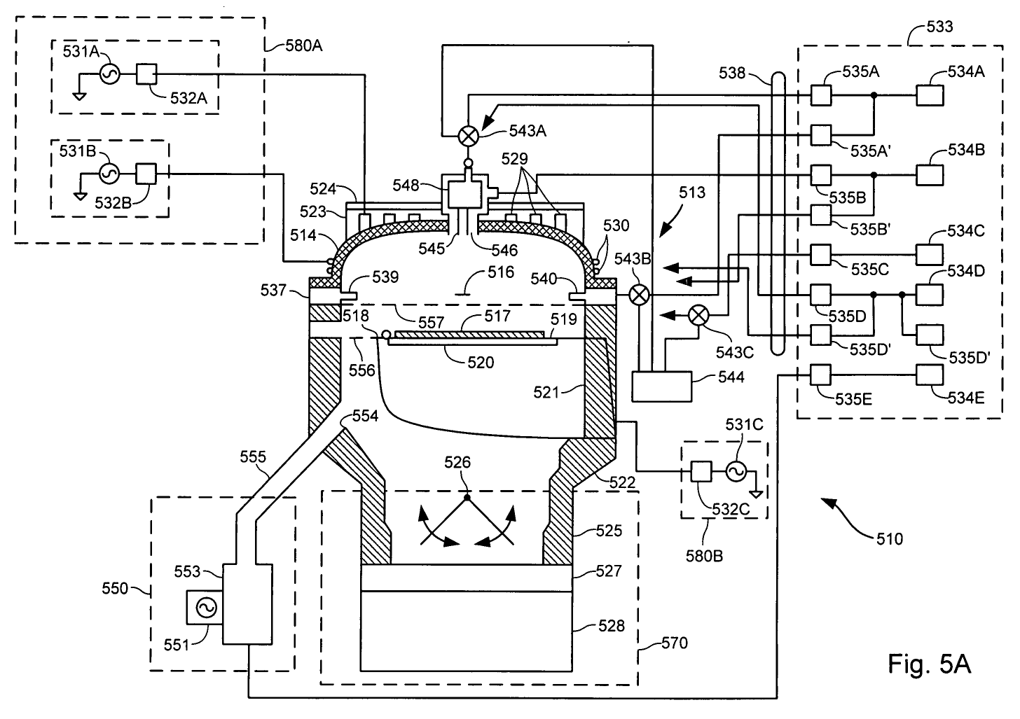

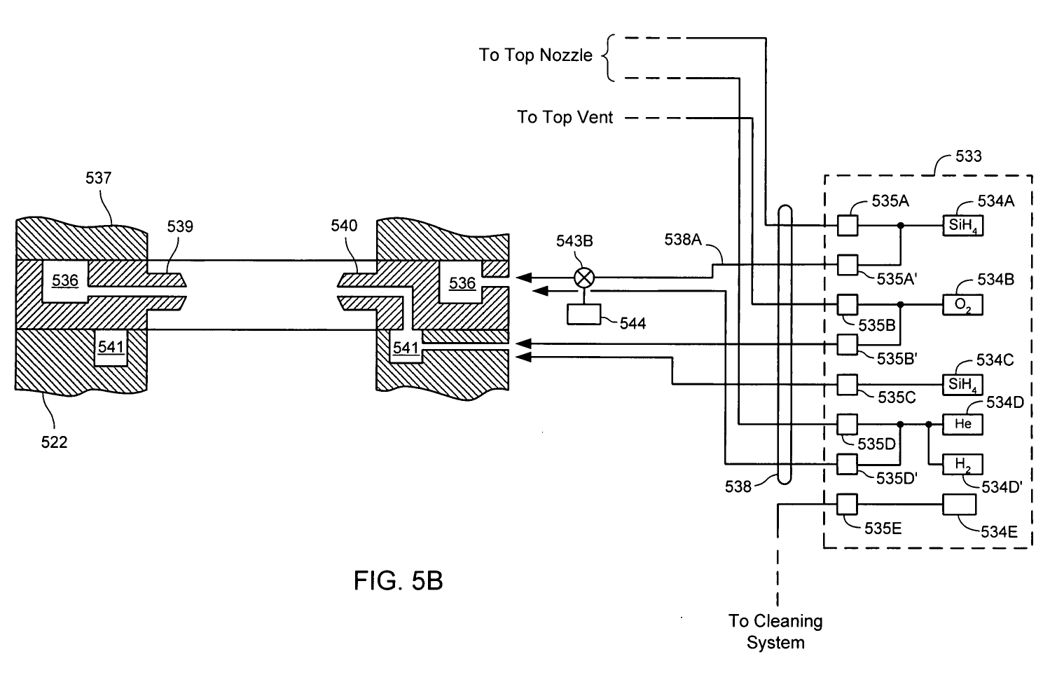

The methods described above may be implemented with a variety of HDP-CVD systems, some of which are described in detail in connection with FIGS. 5A-5C. FIG. 5A schematically illustrates the structure of such an HDP-CVD system 510 in one embodiment. The system 510 includes a chamber 513, a vacuum system 570, a source plasma system 580A, a bias plasma system 580B, a gas delivery system 533, and a remote plasma cleaning system 550.

The upper portion of chamber 513 includes a dome 514, which is made of a ceramic dielectric material, such as aluminum oxide or aluminum nitride. Dome 514 defines an upper boundary of a plasma processing region 516. Plasma processing region 516 is bounded on the bottom by the upper surface of a substrate 517 and a substrate support member 518.

A heater plate 523 and a cold plate 524 surmount, and are thermally coupled to, dome 514. Heater plate 523 and cold plate 524 allow control of the dome temperature to within about ±10° C. over a range of about 100° C. to 200° C. This allows optimizing the dome temperature for the various processes. For example, it may be desirable to maintain the dome at a higher temperature for cleaning or etching processes than for deposition processes. Accurate control of the dome temperature also reduces the flake or particle counts in the chamber and improves adhesion between the deposited layer and the substrate.

The lower portion of chamber 513 includes a body member 522, which joins the chamber to the vacuum system. A base portion 521 of substrate support member 518 is mounted on, and forms a continuous inner surface with, body member 522. Substrates are transferred into and out of chamber 513 by a robot blade (not shown) through an insertion/removal opening (not shown) in the side of chamber 513. Lift pins (not shown) are raised and then lowered under the control of a motor (also not shown) to move the substrate from the robot blade at an upper loading position 557 to a lower processing position 556 in which the substrate is placed on a substrate receiving portion 519 of substrate support member 518. Substrate receiving portion 519 includes an electrostatic chuck 520 that secures the substrate to substrate support member 518 during substrate processing. In a preferred embodiment, substrate support member 518 is made from an aluminum oxide or aluminum ceramic material.

Vacuum system 570 includes throttle body 525, which houses twin-blade throttle valve 526 and is attached to gate valve 527 and turbo-molecular pump 528. It should be noted that throttle body 625 offers minimum obstruction to gas flow, and allows symmetric pumping. Gate valve 527 can isolate pump 528 from throttle body 525, and can also control chamber pressure by restricting the exhaust flow capacity when throttle valve 526 is fully open. The arrangement of the throttle valve, gate valve, and turbo-molecular pump allow accurate and stable control of chamber pressures from between about 1 millitorr to about 2 torr.

The source plasma system 580A includes a top coil 529 and side coil 530, mounted on dome 514. A symmetrical ground shield (not shown) reduces electrical coupling between the coils. Top coil 529 is powered by top source RF (SRF) generator 531A, whereas side coil 530 is powered by side SRF generator 531B, allowing independent power levels and frequencies of operation for each coil. This dual coil system allows control of the radial ion density in chamber 513, thereby improving plasma uniformity. Side coil 530 and top coil 529 are typically inductively driven, which does not require a complimentary electrode. In a specific embodiment, the top source RF generator 531A provides up to 2,500 watts of RF power at nominally 2 MHz and the side source RF generator 531B provides up to 5,000 watts of RF power at nominally 2 MHz. The operating frequencies of the top and side RF generators may be offset from the nominal operating frequency (e.g. to 1.7-1.9 MHz and 1.9-2.1 MHz, respectively) to improve plasma-generation efficiency.

A bias plasma system 580B includes a bias RF (“BRF”) generator 531C and a bias matching network 532C. The bias plasma system 580B capacitively couples substrate portion 517 to body member 522, which act as complimentary electrodes. The bias plasma system 580B serves to enhance the transport of plasma species (e.g., ions) created by the source plasma system 580A to the surface of the substrate. In a specific embodiment, bias RF generator provides up to 5,000 watts of RF power at 13.56 MHz.

RF generators 531A and 531B include digitally controlled synthesizers and operate over a frequency range between about 1.8 to about 2.1 MHz. Each generator includes an RF control circuit (not shown) that measures reflected power from the chamber and coil back to the generator and adjusts the frequency of operation to obtain the lowest reflected power, as understood by a person of ordinary skill in the art. RF generators are typically designed to operate into a load with a characteristic impedance of 50 ohms. RF power may be reflected from loads that have a different characteristic impedance than the generator. This can reduce power transferred to the load. Additionally, power reflected from the load back to the generator may overload and damage the generator. Because the impedance of a plasma may range from less than 5 ohms to over 900 ohms, depending on the plasma ion density, among other factors, and because reflected power may be a function of frequency, adjusting the generator frequency according to the reflected power increases the power transferred from the RF generator to the plasma and protects the generator. Another way to reduce reflected power and improve efficiency is with a matching network.

Matching networks 532A and 532B match the output impedance of generators 531A and 531B with their respective coils 529 and 530. The RF control circuit may tune both matching networks by changing the value of capacitors within the matching networks to match the generator to the load as the load changes. The RF control circuit may tune a matching network when the power reflected from the load back to the generator exceeds a certain limit. One way to provide a constant match, and effectively disable the RF control circuit from tuning the matching network, is to set the reflected power limit above any expected value of reflected power. This may help stabilize a plasma under some conditions by holding the matching network constant at its most recent condition.

Other measures may also help stabilize a plasma. For example, the RF control circuit can be used to determine the power delivered to the load (plasma) and may increase or decrease the generator output power to keep the delivered power substantially constant during deposition of a layer.

A gas delivery system 533 provides gases from several sources, 534A-534E chamber for processing the substrate via gas delivery lines 538 (only some of which are shown). As would be understood by a person of skill in the art, the actual sources used for sources 534A-534E and the actual connection of delivery lines 538 to chamber 513 varies depending on the deposition and cleaning processes executed within chamber 513. Gases are introduced into chamber 513 through a gas ring 537 and/or a top nozzle 545. FIG. 5B is a simplified, partial cross-sectional view of chamber 513 showing additional details of gas ring 537.

In one embodiment, first and second gas sources, 534A and 534B, and first and second gas flow controllers, 535A′ and 535B′, provide gas to ring plenum 536 in gas ring 537 via gas delivery lines 538 (only some of which are shown). Gas ring 537 has a plurality of source gas nozzles 539 (only one of which is shown for purposes of illustration) that provide a uniform flow of gas over the substrate. Nozzle length and nozzle angle may be changed to allow tailoring of the uniformity profile and gas utilization efficiency for a particular process within an individual chamber. In a preferred embodiment, gas ring 537 has 12 source gas nozzles made from an aluminum oxide ceramic.

Gas ring 537 also has a plurality of oxidizer gas nozzles 540 (only one of which is shown), which in a preferred embodiment are co-planar with and shorter than source gas nozzles 539, and in one embodiment receive gas from body plenum 541. In some embodiments it is desirable not to mix source gases and oxidizer gases before injecting the gases into chamber 513. In other embodiments, oxidizer gas and source gas may be mixed prior to injecting the gases into chamber 513 by providing apertures (not shown) between body plenum 541 and gas ring plenum 536. In one embodiment, third, fourth, and fifth gas sources, 534C, 534D, and 534D′, and third and fourth gas flow controllers, 535C and 535D′, provide gas to body plenum via gas delivery lines 538. Additional valves, such as 543B (other valves not shown), may shut off gas from the flow controllers to the chamber. In implementing certain embodiments of the invention, source 534A comprises a silane SiH₄ source, source 534B comprises a molecular oxygen O₂ source, source 534C comprises a silane SiH₄ source, source 534D comprises a helium He source, and source 534D′ comprises a molecular hydrogen H₂ source.

In embodiments where flammable, toxic, or corrosive gases are used, it may be desirable to eliminate gas remaining in the gas delivery lines after a deposition. This may be accomplished using a 3-way valve, such as valve 543B, to isolate chamber 513 from delivery line 538A and to vent delivery line 538A to vacuum foreline 544, for example. As shown in FIG. 5A, other similar valves, such as 543A and 543C, may be incorporated on other gas delivery lines. Such three-way valves may be placed as close to chamber 513 as practical, to minimize the volume of the unvented gas delivery line (between the three-way valve and the chamber). Additionally, two-way (on-off) valves (not shown) may be placed between a mass flow controller (“MFC”) and the chamber or between a gas source and an MFC.

Referring again to FIG. 5A, chamber 513 also has top nozzle 545 and top vent 546. Top nozzle 545 and top vent 546 allow independent control of top and side flows of the gases, which improves film uniformity and allows fine adjustment of the film's deposition and doping parameters. Top vent 546 is an annular opening around top nozzle 545. In one embodiment, first gas source 534A supplies source gas nozzles 539 and top nozzle 545. Source nozzle MFC 535A′ controls the amount of gas delivered to source gas nozzles 539 and top nozzle MFC 535A controls the amount of gas delivered to top gas nozzle 545. Similarly, two MFCs 535B and 535B′ may be used to control the flow of oxygen to both top vent 546 and oxidizer gas nozzles 540 from a single source of oxygen, such as source 534B. The gases supplied to top nozzle 545 and top vent 546 may be kept separate prior to flowing the gases into chamber 513, or the gases may be mixed in top plenum 548 before they flow into chamber 513. Separate sources of the same gas may be used to supply various portions of the chamber.

A remote microwave-generated plasma cleaning system 550 is provided to periodically clean deposition residues from chamber components. The cleaning system includes a remote microwave generator 551 that creates a plasma from a cleaning gas source 534E (e.g., molecular fluorine, nitrogen trifluoride, other fluorocarbons or equivalents) in reactor cavity 553. The reactive species resulting from this plasma are conveyed to chamber 513 through cleaning gas feed port 554 via applicator tube 555. The materials used to contain the cleaning plasma (e.g., cavity 553 and applicator tube 555) must be resistant to attack by the plasma. The distance between reactor cavity 553 and feed port 554 should be kept as short as practical, since the concentration of desirable plasma species may decline with distance from reactor cavity 553. Generating the cleaning plasma in a remote cavity allows the use of an efficient microwave generator and does not subject chamber components to the temperature, radiation, or bombardment of the glow discharge that may be present in a plasma formed in situ. Consequently, relatively sensitive components, such as electrostatic chuck 520, do not need to be covered with a dummy wafer or otherwise protected, as may be required with an in situ plasma cleaning process.

An example of a system that may incorporate some or all of the subsystems and routines described above would be the ULTIMA™ system, manufactured by APPLIED MATERIALS, INC., of Santa Clara, Calif., configured to practice the present invention. Further details of such a system are disclosed in commonly assigned U.S. Pat. No. 6,170,428, filed Jul. 15, 1996, entitled “Symmetric Tunable Inductively-Coupled HDP-CVD Reactor,” having Fred C. Redeker, Farhad Moghadam, Hirogi Hanawa, Tetsuya Ishikawa, Dan Maydan, Shijian Li, Brian Lue, Robert Steger, Yaxin Wang, Manus Wong and Ashok Sinha listed as co-inventors, the disclosure of which is incorporated herein by reference. The described system is for exemplary purpose only. It would be a matter of routine skill for a person of skill in the art to select an appropriate conventional substrate processing system and computer control system to implement the present invention.

Those of ordinary skill in the art will realize that processing parameters can vary for different processing chambers and different processing conditions, and that different precursors can be used without departing from the spirit of the invention. Other variations will also be apparent to persons of skill in the art. These equivalents and alternatives are intended to be included within the scope of the present invention. Therefore, the scope of this invention should not be limited to the embodiments described, but should instead be defined by the following claims.

1. A method for depositing a film over a substrate, the method comprising:
flowing a process gas to a process chamber, the process gas comprising a silicon-containing gas and an oxygen-containing gas;
flowing a fluent gas to the process chamber, the fluent gas comprising a flow of helium and a flow of molecular hydrogen, the flow of molecular hydrogen being provided at a flow rate less than 20% of a flow rate of the helium;
forming a plasma in the process chamber from the process gas and fluent gas, the plasma having a density greater than 10¹¹ ions/cm³; and
depositing the film over the substrate with the plasma.

2. The method recited in claim 1 wherein the flow of molecular hydrogen is provided at a flow rate less than 10% of the flow rate of the helium.

3. The method recited in claim 1 wherein the flow of molecular hydrogen is provided at a flow rate less than 5% of the flow rate of the helium.

4. The method recited in claim 1 wherein the fluent gas further comprises a flow of an inert gas at a flow rate less than 10% of the flow rate of the helium.

5. The method recited in claim 1 wherein the flow rate of the helium is between 100 and 1000 sccm.

6. The method recited in claim 1 further comprising applying a negative bias to the substrate.

7. The method recited in claim 1 wherein an interior pressure of the process chamber is maintained less than 10 mtorr.

8. The method recited in claim 1 wherein the silicon-containing gas comprises SiH₄.

9. The method recited in claim 1 wherein the oxygen-containing gas comprises O₂.

10. A method for depositing a film over a substrate having adjacent raised features to fill a gap between the adjacent raised features, the gap having a width between 90 and 150 nm the method comprising:
flowing a process gas to a process chamber, the process gas comprising a silicon-containing gas and an oxygen-containing gas;
flowing a fluent gas to the process chamber, the fluent gas consisting essentially of a flow of helium and a flow of molecular hydrogen, the flow of molecular hydrogen being provided at a flow rate less than 10% of a flow rate of the helium;
forming a plasma in the process chamber from the process gas and fluent gas, the plasma having a density greater than 10¹¹ ions/cm³;
maintaining an interior pressure of the process chamber less than 10 mtorr; and
depositing the film in the gap with the plasma.

11. The method recited in claim 10 wherein the flow of molecular hydrogen is provided at a flow rate less than 10% of the flow rate of the helium.

12. The method recited in claim 10 wherein the flow rate of the helium is between 100 and 1000 sccm.

13. The method recited in claim 10 wherein the flow rate of the helium is between 300 and 500 sccm.

14. The method recited in claim 10 wherein the silicon-containing gas comprises SiH₄ and the oxygen-containing gas comprises O₂.

15. A method for depositing an undoped silicate glass film over a substrate having adjacent raised features to fill a gap between the adjacent raised features, the method comprising:
flowing SiH₄, O₂, He, and H₂ to the process chamber, the He being provided at a flow rate between 100 and 1000 sccm, and the H₂ being provided at a flow rate less than 20% of the flow rate of the He;
forming a plasma from gas flowed into the process chamber, the plasma having a density greater than 10¹¹ ions/cm³;
maintaining an interior pressure of the process chamber less than 10 mtorr; and
depositing the undoped silicate glass film in the gap with the plasma.
